(19) United States
(12) Patent Application Publication
(10) Pub. No.: US 2006/0292762 A1
(43) Pub. Date: Dec. 28, 2006

(54) Replacement gate field effect transistor with germanium or SiGe channel and manufacturing method for same using gas-cluster ion irradiation

(75) Inventors: John O. Borland, S. Hamilton, MA (US); Wesley J. Skinner, Andover, MA (US)

Correspondence Address: BURNS & LEVINSON, LLP;(FORMERLY PERKINS SMITH & COHEN LLP), 125 SUMMER STREET, BOSTON, MA, 02110, US

(73) Assignee: Epion Corporation, Billerica, MA (US)

(21) Appl. No.: 11/472,136

(22) Filed: Jun. 21, 2006

Related U.S. Application Data
(60) Provisional application No. 60/692,795, filed on Jun. 22, 2005.

(51) Int. Cl. H01L 21/84

(52) U.S. Cl. 438/151

(57) ABSTRACT

A self-aligned MISFET transistor (500H) on a silicon substrate (502), but having a graded SiGe channel or a Ge channel. The channel (526) is formed using gas-cluster ion beam (524) irradiation and provides higher channel mobility than conventional silicon channel MISFETs. A manufacturing method for such a transistor is based on a replacement gate process flow augmented with a gas-cluster ion beam processing step or steps to form the SiGe or Ge channel. The channel may also be doped by gas-cluster ion beam processing either as an auxiliary step or simultaneously with formation of the increased mobility channel.

### CROSS REFERENCE TO RELATED PATENT APPLICATIONS

This application claims priority of U.S. Provisional Application Ser. No. 60/692,795 entitled “Replacement Gate Field Effect Transistor with Germanium Channel and Manufacturing Method for Same using Gas-Cluster Ion Irradiation”, filed Jun. 22, 2005, the contents of which are incorporated herein by reference.

### FIELD OF THE INVENTION

This invention relates generally to a semiconductor field effect transistor and its manufacturing method, and more specifically, relates to a field effect transistor having a germanium channel and its manufacturing method using gas-cluster ion irradiation.

### BACKGROUND OF THE INVENTION

The characteristics of semiconductor materials such as, silicon, germanium, silicon-germanium (SiGe), and other semiconductor materials have been exploited to form a large variety of useful devices in the fields of electronics, communications, electro-optics, and nano-technology. There has been a relentless push and marked progress toward improving integrated circuit density and toward producing superior device performance, including faster operation, higher current drive capability, and lower power dissipation.

In the effort to improve performance, there has been a tendency toward the use of metal-insulator-semiconductor field effect transistor (MISFET) designs that utilize high dielectric constant (high-k) gate dielectrics and (preferably) metal gate electrodes rather than the older conventional SiO₂ dielectric and polysilicon gate electrodes. Use of high-k gate dielectric with a metal gate has, in many applications, proven disadvantageous because of a poor heat resistance of the combination. Since high-temperature heat treatment is often a desirable step in semiconductor processing, techniques have been developed to permit the use of metal gate electrodes with high-k gate dielectrics while still permitting the use of high-temperature treatment at desirable steps in the fabrication process.

One of these techniques is to modify the process to a so-called “dummy” gate or “replacement” gate process, in which a more conventional high-temperature-tolerant gate structure (dummy gate) is fabricated and kept in place during high-temperature steps, and after high-temperature processing, removed. After high-temperature processing has been completed, a (replacement) gate electrode and high-k gate dielectric structure is fabricated for high performance use in the finished device. The “dummy” or “replacement” gate process is known in the art and is described in numerous US patents including, for example, U.S. Pat. No. 5,960,270 and U.S. Pat. No. 6,667,199. The technique is applied to both n-channel MISFETs and p-channel MISFETs.

Numerous materials are being used and/or studied for use as high-k gate dielectric materials. The conventional gate dielectric material, SiO₂, has a dielectric constant of about 3.9. The dielectric constant of Si₃N₄ is about 7.8 By doping SiO₂ with nitrogen to produce heavily nitrogen doped silicon oxynitrides (SiON) of various stoichiometries, a resulting dielectric constant (in the range of from about 5.0 to about 7.0) approaching that of Si₃N₄ is obtained without some of the disadvantages of Si₃N₄. More recently, hafnium-based dielectrics having various stoichiometries have been utilized. These include, for example, nitrided hafnium silicates (HfSiON), hafnium silicate (HfSiO), and hafnium aluminates (HfAlO), and these achieve dielectric constants in the range of about 9 to about 26. Such high-k materials are preferred for some presently manufactured devices and for future improvements to semiconductor device performance. As the term is used herein, the term “high-k” or “high-k dielectric” is intended to refer to dielectrics having a dielectric constant greater than about 5.0. As used herein, the term “MISFET” is intended to include field effect transistors having metal or polysilicon gate electrodes and employing a high-k gate insulator material, not including SiO₂, but including silicon oxynitrides and other high-k dielectric materials, without limitation.

The use of some high-k gate dielectric materials, including hafnium-based dielectrics, has been known to cause a reduction in the channel mobility of a MISFET formed using such gate dielectrics. This decreases device speed performance. Accordingly, along with the use of high-k dielectrics, channel mobility enhancement techniques are required to optimize MISFET device performance in practical circuits.

There has been interest in the use of global strained-silicon on SiGe layers for substrates upon which to build improved mobility channels, but the cost is high and indications are that the resulting mobility improvement disappears as gate lengths scale below 0.2 microns. Selective localized SiGe has also been used to produce strained channels to improve mobility, but such localized-strain techniques have only produced mobility improvements of less than 2×, and greater improvement will be required for future devices. For this reason the industry has begun studying germanium CMOS devices which promise about 2.6× improvement in electron mobility and 4.2× improvement in hole mobility. Several groups have reported improved p-channel MISFET devices, but n-channel MISFET devices have so-far shown little or no improvement by the use of germanium substrates. It has been proposed that a reason for the poor improvement in n-channel MISFET devices is the poor activation of n-type (as used for the source/drain regions) dopants in germanium. Also, in comparison with silicon, germanium substrates or blanket germanium films on silicon substrates are costly.

The use of a gas-cluster ion beam (GCIB) for etching, cleaning, and smoothing surfaces is known (see for example, U.S. Pat. No. 5,814,194, Deguchi, et al.) in the art. GCIBs have also been employed for assisting the deposition of films from vaporized carbonaceous materials (see for example, U.S. Pat. No. 6,416,820, Yamada, et al.) As the term is used herein, gas-clusters are nano-sized aggregates of materials that are gaseous under conditions of standard temperature and pressure. Such clusters may comprise aggregates of from a few to several thousand molecules or more loosely bound to form the cluster. The clusters can be ionized by electron bombardment or other means, permitting them to be formed into directed beams of controllable energy. Such ions each typically carry positive charges of q·e (where e is the magnitude of the electronic charge and q is an integer of from one to several representing the charge state of the cluster ion). The larger sized clusters are often the most useful because of their ability to carry substantial energy per cluster ion, while yet having only modest energy per molecule. The clusters disintegrate on impact, with each individual molecule carrying only a small fraction of the total cluster energy. Consequently, the impact effects of large clusters are substantial, but are limited to a very shallow surface region.

Apparatus for creating and accelerating such GCIBs are described in the U.S. Pat. No. 5,814,194 patent previously cited. Presently available ion cluster sources produce clusters ions having a wide distribution of sizes, N, up to N of several thousand or even a few tens of thousands (where N=the number of molecules in each cluster.) For gas cluster ion beam infusion, the most effective gas cluster ions are those having sizes in the range of from about 100 molecules to about 15 thousand molecules and having distributions with a most probable size of from about 1000 molecules to about 10,000 molecules.

### SUMMARY OF THE INVENTION

By providing a germanium or SiGe channel in a p-channel MISFET or n-channel MISFET, carrier mobility is improved. A germanium or SiGe channel can be formed in a FET formed on a silicon or silicon-on-insulator substrate by using selective Ge infusion by energetic gas cluster ion beam irradiation. This can be achieved using a “replacement” gate process flow and masking step where the Ge or SiGe channel is formed after source-drain extension formation and after source-drain formation. The Ge is infused through the replacement gate mask prior to high-k gate dielectric deposition and gate formation. The infused Ge or SiGe channel may be doped with p-type or n-type dopants and may be activated and annealed at low temperatures with minimal diffusion. The infused Ge is limited to only the channel region and not the source-drain extension regions nor the deep source-drain regions. After gas-cluster ion beam Ge infusion, the high-k gate dielectric gate insulator film is deposited, followed by fabrication of a gate electrode. Infusion of Ge into Si to form Ge and/or SiGe films by GCIB irradiation is a subject of US Patent Application publication 2005/0181621A1 by Borland et al. and the entire contents thereof are incorporated herein by reference.

It is therefore an object of this invention to provide both p-channel MISFETs and n-channel MISFETs having metal or polysilicon gates, high-k gate dielectric insulators, and germanium or SiGe channels fabricated on a silicon or silicon-on-insulator substrate.

It is another object of this invention to provide methods for the formation of both p-channel MISFETs and n-channel MISFETs having metal or polysilicon gates, high-k gate dielectric insulators, and germanium or SiGe channels fabricated on a silicon or silicon-on-insulator substrate by the selective infusion of germanium by energetic gas-cluster ion irradiation.

It is a further object of this invention to provide methods for the formation of both p-channel MIS- and n-channel MISFETs having metal or polysilicon gates, high-k gate dielectric insulators, and germanium or SiGe channels fabricated on a silicon or silicon-on-insulator substrate by the selective infusion of germanium and dopant by energetic gas-cluster ion irradiation.

The objects set forth above as well as further and other objects and advantages of the present invention are achieved by the embodiments of the invention described hereinbelow.

### BRIEF DESCRIPTION OF THE FIGURES

For a better understanding of the present invention, together with other and further objects thereof, reference is made to the accompanying drawing and detailed description, wherein:

FIG. 1 is a schematic showing the basic elements of a prior art GCIB processing apparatus that uses an electrostatically scanned beam;

FIG. 2 is a schematic showing the basic elements of a prior art GCIB processing apparatus that uses a stationary beam with mechanical scanning of the workpiece and that includes provision for mixing source gases;

FIG. 3 is a graph showing SIMS measurement of a germanium and boron infused surface film on a silicon substrate, the film having been formed by gas-cluster ion processing suitable for use in the invention;

FIG. 4 is a graph comparing SIMS measurements of germanium-containing gas-cluster ion beam processing of a silicon semiconductor surface under two different processing conditions, one resulting in infusion of germanium into the silicon and one resulting in formation of a germanium film on the surface of the silicon, both illustrating concepts applicable to the invention; and

FIGS. 5A, 5B, 5C, 5D, 5E, 5F, 5G, and 5H are schematics showing sequential steps in the formation of an n-channel enhancement mode MISFET according to the invention.

### DETAILED DESCRIPTION OF THE INVENTION

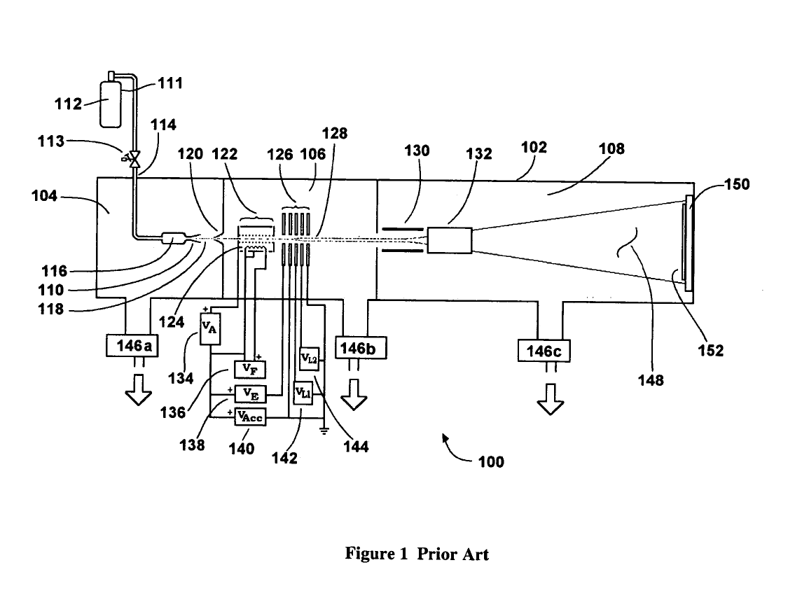

FIG. 1 shows a schematic of the basic elements of a typical configuration for a processing apparatus 100 for generating a GCIB in accordance with the present invention. Apparatus 100 may be described as follows: a vacuum vessel 102 is divided into three communicating chambers, a source chamber 104, an ionization/acceleration chamber 106, and a processing chamber 108. The three chambers are evacuated to suitable operating pressures by vacuum pumping systems 146a, 146b, and 146c, respectively. A condensable source gas 112 (for example argon or N₂) stored in a gas storage cylinder 111 is admitted under pressure through gas metering valve 113 and gas feed tube 114 into stagnation chamber 116 and is ejected into the substantially lower pressure vacuum through a properly shaped nozzle 110. A supersonic gas jet 118 results. Cooling, which results from the expansion in the jet, causes a portion of the gas jet 118 to condense into clusters, each consisting of from several to several thousand weakly bound atoms or molecules. A gas skimmer aperture 120 partially separates the gas molecules that have not condensed into a cluster jet from the cluster jet so as to minimize pressure in the downstream regions where such higher pressures would be detrimental (e.g., ionizer 122, high voltage electrodes 126, and processing chamber 108). Suitable condensable source gases 112 include, but are not necessarily limited to argon, nitrogen, carbon dioxide, oxygen, and other gases.

After the supersonic gas jet 118 containing gas-clusters has been formed, the clusters are ionized in an ionizer 122. The ionizer 122 is typically an electron impact ionizer that produces thermoelectrons from one or more incandescent filaments 124 and accelerates and directs the electrons causing them to collide with the gas-clusters in the gas jet 118, where the jet passes through the ionizer 122. The electron impact ejects electrons from the clusters, causing a portion the clusters to become positively ionized. A set of suitably biased high voltage electrodes 126 extracts the cluster ions from the ionizer, forming a beam, then accelerates them to a desired energy (typically from 1 keV to several tens of keV) and focuses them to form a GCIB 128. Filament power supply 136 provides filament voltage V_{f} to heat the ionizer filament 124. Anode power supply 134 provides anode voltage V_{A} to accelerate thermoelectrons emitted from filament 124 to cause them to irradiate the cluster containing gas jet 118 to produce ions. Extraction power supply 138 provides extraction voltage V_{E} to bias a high voltage electrode to extract ions from the ionizing region of ionizer 122 and to form a GCIB 128. Accelerator power supply 140 provides acceleration voltage V_{Acc} to bias a high voltage electrode with respect to the ionizer 122 so as to result in a total GCIB acceleration equal to V_{Acc}. One or more lens power supplies (142 and 144 shown for example) may be provided to bias high voltage electrodes with focusing voltages (V_{L1} and V_{L2} for example) to focus the GCIB 128.

A workpiece 152, which may be a semiconductor wafer or other workpiece to be processed by GCIB processing, is held on a workpiece holder 150, disposed in the path of the GCIB 128. Since most applications contemplate the processing of large workpieces with spatially uniform results, a scanning system is desirable to uniformly scan the GCIB 128 across large areas to produce spatially homogeneous results. Two pairs of orthogonally oriented electrostatic scan plates 130 and 132 can be utilized to produce a raster or other scanning pattern across the desired processing area. When beam scanning is performed, the GCIB 128 is converted into a scanned GCIB 148, which scans the entire surface of workpiece 152.

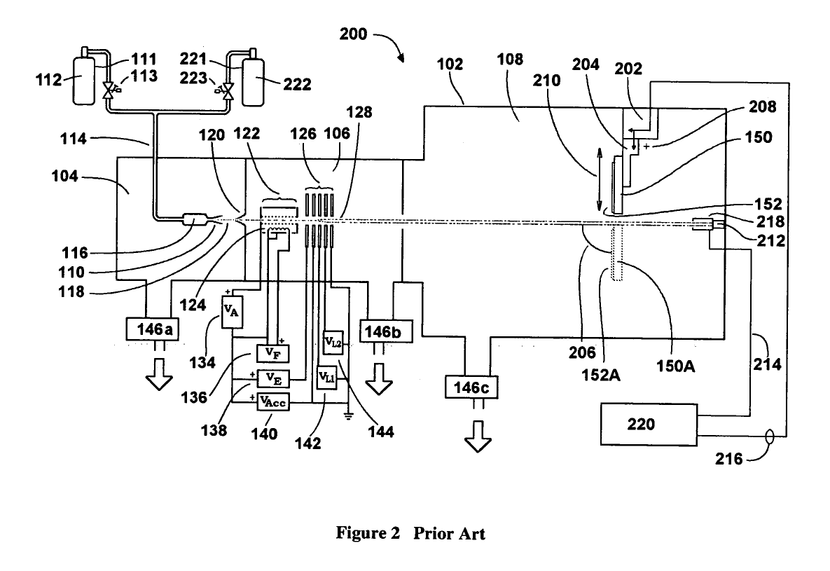

FIG. 2 shows a schematic of the basic elements of a prior art mechanically scanning GCIB processing apparatus 200 having a stationary beam with a mechanically scanned workpiece 152, and having a conventional faraday cup for beam measurement and a conventional thermionic neutralizer. GCIB formation is similar to as shown in FIG. 1, except there is additional provision for an optional second source gas 222 (typically different from the source gas 112) stored in a gas storage cylinder 221 with a gas metering valve 223 and connecting through gas feed tube 114 into stagnation chamber 116. Although not shown, it will be readily appreciated by those of skill in the art that three or more source gases can easily be arranged for by adding additional gas storage cylinders, plumbing, and valves. This multiple gas arrangement allows for controllably selecting between two differing source gasses 112 and 222 or for controllably forming a mixture of two (or more) source gasses for use in forming gas-clusters. It is further understood that the source gases, 112, and 222, may themselves be mixtures of gases, for examples argon plus 1% diborane, or argon plus 5% germane. In addition, in the mechanically scanning GCIB processing apparatus 200 of FIG. 2, the GCIB 128 is stationary (not electrostatically scanned as in the GCIB processing apparatus 100) and the workpiece 152 is mechanically scanned through the GCIB 128 to distribute the effects of the GCIB 128 over a surface of the workpiece 152.

An X-scan actuator 202 provides linear motion of the workpiece holder 150 in the direction of X-scan motion 208 (into and out of the plane of the paper). A Y-scan actuator 204 provides linear motion of the workpiece holder 150 in the direction of Y-scan motion 210, which is typically orthogonal to the X-scan motion 208. The combination of X-scanning and Y-scanning motions moves the workpiece 152, held by the workpiece holder 150 in a raster-like scanning motion through GCIB 128 to cause a uniform irradiation of a surface of the workpiece 152 by the GCIB 128 for uniform processing of the workpiece 152. The workpiece holder 150 disposes the workpiece 152 at an angle with respect to the axis of the GCIB 128 so that the GCIB 128 has an angle of beam incidence 206 with respect to the workpiece 152 surface. The angle of beam incidence 206 may be 90 degrees or some other angle, but is typically 90 degrees or very near 90 degrees. During Y-scanning, the workpiece 152 held by workpiece holder 150 moves from the position shown to the alternate position “A”, indicated by the designators 152A and 150A respectively. Notice that in moving between the two positions, the workpiece 152 is scanned through the GCIB 128 and in both extreme positions, is moved completely out of the path of the GCIB 128 (over-scanned). Though not shown explicitly in FIG. 2, similar scanning and over-scan is performed in the (typically) orthogonal X-scan motion 208 direction (in and out of the plane of the paper).

A beam current sensor 218 is disposed beyond the workpiece holder 150 in the path of the GCIB 128 so as to intercept a sample of the GCIB 128 when the workpiece holder 150 is scanned out of the path of the GCIB 128. The beam current sensor 218 is typically a faraday cup or the like, closed except for a beam-entry opening, and is affixed to the wall of the vacuum vessel 102 with an electrically insulating mount 212.

A controller 220, which may be a microcomputer based controller connects to the X-scan actuator 202 and the Y-scan actuator 204 through electrical cable 216 and controls the X-scan actuator 202 and the Y-scan actuator 204 so as to place the workpiece 152 into or out of the GCIB 128 and to scan the workpiece 152 uniformly relative to the GCIB 128 to achieve uniform processing of the workpiece 152 by the GCIB 128. Controller 220 receives the sampled beam current collected by the beam current sensor 218 by way of lead 214 and thereby monitors the GCIB and controls the GCIB dose received by the workpiece 152 by removing the workpiece 152 from the GCIB 128 when a predetermined desired dose has been delivered.

Upon impact of an energetic gas-cluster on the surface of a solid target, penetration of the atoms of the cluster into the target surface is typically very shallow because the penetration depth is limited by the low energy of each individual constituent atom and results primarily from a transient thermal effect that occurs during the gas-cluster ion impact. As used herein, the terms “energetic gas cluster” and “energetic gas cluster ion” and “energetic gas cluster ion beam” are intended to mean gas cluster ion(s) or a gas cluster ion beam in which the gas cluster ions have been accelerated by falling through an electric potential difference (acceleration voltage), typically on the order of from about a thousand volts to as much as several tens of kilovolts. Gas-clusters dissociate upon impact and the individual gas atoms then become free to recoil and possibly escape from the surface of the target. Other than energy carried away by the escaping individual gas atoms, the total energy of the energetic cluster prior to impact becomes deposited into the impact zone on the target surface. This makes ion clusters effective for a variety of surface modification processes, without the tendency to produce deeper subsurface damage characteristic of conventional ion beam processing. The depth dimensions of a target impact zone are dependent on the energy of the cluster but are of the order of the cross-sectional dimensions of the impacting cluster and are small, for example, roughly 30 Angstroms in diameter for a cluster comprised of 1000 atoms. Because of the deposition of most of the total energy carried by the cluster into the small impact zone on the target, an intense but highly localized thermal transient occurs within the target material at the impact site. The thermal transient dissipates quickly as energy is lost from the impact zone by conduction deeper into the target and the gross target is scarcely heated at all. Duration of the thermal transient is determined by the conductivity of the target material but will typically be less than 10⁻⁶ second.

Near a cluster impact site, a volume of the target surface can momentarily reach temperatures of many hundreds to several thousands of degrees Kelvin. As an example, impact of a cluster carrying 10 keV total energy is estimated to be capable of producing a momentary temperature increase of about 2000 degrees Kelvin throughout a highly agitated, approximately hemispherical zone extending to about 100 Angstroms below a silicon surface.

Following initiation of an elevated temperature transient within the target volume below an energetic cluster impact site, the affected zone cools rapidly. Some of the cluster constituents escape during this process, while others remain behind and become incorporated into the surface. A portion of the original surface material may also be removed by sputtering or like effects. In general, the more volatile and inert constituents of the cluster are more likely to escape, while the less volatile and more chemically reactive constituents are more likely to become incorporated into the surface. Although the actual process is likely much more complex, it is convenient to think of the cluster impact site and the surrounded affected zone as a “melt zone” wherein the cluster atoms may briefly interact and mix with the substrate surface and wherein the cluster materials either escape the surface or become infused into the surface to the depth of the affected zone. The terms “infusion” and “infusing” are used herein to refer to this process and to distinguish it from ion “implantation” or “implanting,” a very different process that produces very different results. Unlike conventional ion implantation, GCIB infusion does not introduce significant amounts of power into the processed substrate and, thus, may be performed as a low (i.e., room) temperature process that does not result in any significant heating of the substrate. Noble gases in the energetic cluster ion, such as argon and xenon, for example, being volatile and non-reactive, have a high probability of escape from the affected zone, while materials such as boron, germanium, and phosphorus, for example, being less volatile and more likely to form chemical bonds, are more likely to remain in the affected zone and to become incorporated in the surface of the substrate.

Noble inert gases such as argon and xenon, for example, not for limitation, can be mixed with gases containing germanium and with gases that contain elements that act as dopants for semiconductor materials, boron, phosphorous, antimony and arsenic, for example, to form compound gas-clusters containing different selected elements. Such gas-clusters can be formed with GCIB processing equipment as shown in FIGS. 1 and 2, by using suitable source gas mixtures as the source gas for gas-cluster ion beam generation, or by feeding two or more gases (or gas mixtures) into the gas-cluster ion generating source and allowing them to mix in the source. Germanium-containing gases such as germane (GeH₄) or germanium tetrafluoride (GeF₄), for example, may be employed for incorporating germanium into gas-clusters. Dopant-containing gases such as diborane (B₂H₆), boron trifluoride (BF₃), phosphine (PH₃), phosphorous pentafluoride (PF₅), arsine (AsH₃), arsenic pentafluoride (AsF₅), and stibine (SbH₃) as examples, as well as other compounds that are available as gases under conditions of standard temperature and pressure, may be employed for incorporating dopant atoms into gas-clusters. Argon and germane, for example, can be mixed to make a source gas for forming clusters to infuse germanium. As another example, argon, germane, and diborane can be mixed to form a source gas for forming clusters containing germanium and boron to infuse germanium and boron. As still another example, argon, germane, and phosphine can be mixed to form a source gas for forming clusters containing both germanium and phosphorus for infusing germanium and phosphorus into a surface. Although it is preferred to incorporate a noble inert gas in gas mixtures used for infusion, it is not essential to the practice of this invention. A germanium-containing gas, a dopant-containing gas, or a mixture of germanium-containing gas(es) and dopant-containing gas(es) containing no noble inert gas can also be employed in the practice of this invention.

For some semiconductor products, an important requirement for the introduction of dopants into the semiconductor surface or for the formations of films is that the maximum depth to which the dopant has been introduced, or that the maximum thickness of the formed film be rather shallow, on the order of a few hundred angstroms or less. GCIBs are particularly suited for formation and processing of shallow films. While the gas-cluster ions may be accelerated to tens of keV of energy, because the clusters typically consist of thousands of atoms, individual atoms have little energy and do not ballistically penetrate the irradiated surface to great depths as occurs in conventional ion implantation and other monomer ion processes. By controlling the energy of the gas-cluster, one can control the depth of energetic gas-cluster impact effects and, through such control, films of 100 angstroms or even less can be formed and/or processed. The infused films tend to be amorphous or polycrystalline, but they can be converted to crystalline films by applying a thermal annealing step, either a rapid anneal or a furnace anneal, preferably a non-diffusing or low-diffusing anneal such as low-temperature solid phase epitaxial regrowth.

FIG. 3 is a graph showing results of SIMS measurement of an infused doped Ge film formed by GCIB infusion as may be employed for practice of the invention. In this example, a gas-cluster ion beam processing system similar to that shown in FIG. 2 was used to process the surface of a silicon semiconductor wafer. A mixture of 5% germane (GeH₄) in argon was used as one source gas for gas-cluster formation, while a mixture of 1% diborane (B₂H₆) in argon was used as a second source gas for gas-cluster formation. The diborane had boron 10B and 11B isotopes in their naturally occurring ratio. The two source gases were mixed as they flowed into the stagnation chamber—the germane mixture was fed at a rate of 300 sccm and the diborane mixture was fed at a rate of 75 sccm. The ionized gas-cluster ion beam was accelerated by 5 kV acceleration voltage and a dose of 1×10¹⁵ gas-cluster ions/cm² was irradiated onto the silicon wafer. The SIMS analysis shows concentrations of germanium and boron as a function of depth and confirms that a surface infused with germanium ions and simultaneously infused with boron ions for doping the silicon/germanium layer has been formed. In the graph, the curve marked “Ge” represents the germanium concentration, the curve marked “10B” represents the concentration of the 10B isotope of boron, and the curve marked “11B” represents the concentration of the 10B tope of boron. The SIMS concentration axis is not accurately calibrated for germanium, but surface XPS measurements confirm that germanium concentrations on the order of 20 atomic percent are achieved and that by varying process parameters germanium concentrations of from a few atomic percent to at least several tens of atomic percent are achievable. Germanium concentrations within this range are useful for producing strains in silicon for enhancing carrier mobility. Note that the boron doping depth is approximately 100 angstroms, which is very shallow and well suited for the formation of shallow junctions. The doped germanium infusion region can be annealed and activated using a thermal treatment. Low temperature thermal treatments of about 550-600 degrees C. can be used, but in general better crystallinity results from higher temperature treatments, around 900 degrees C., for example.

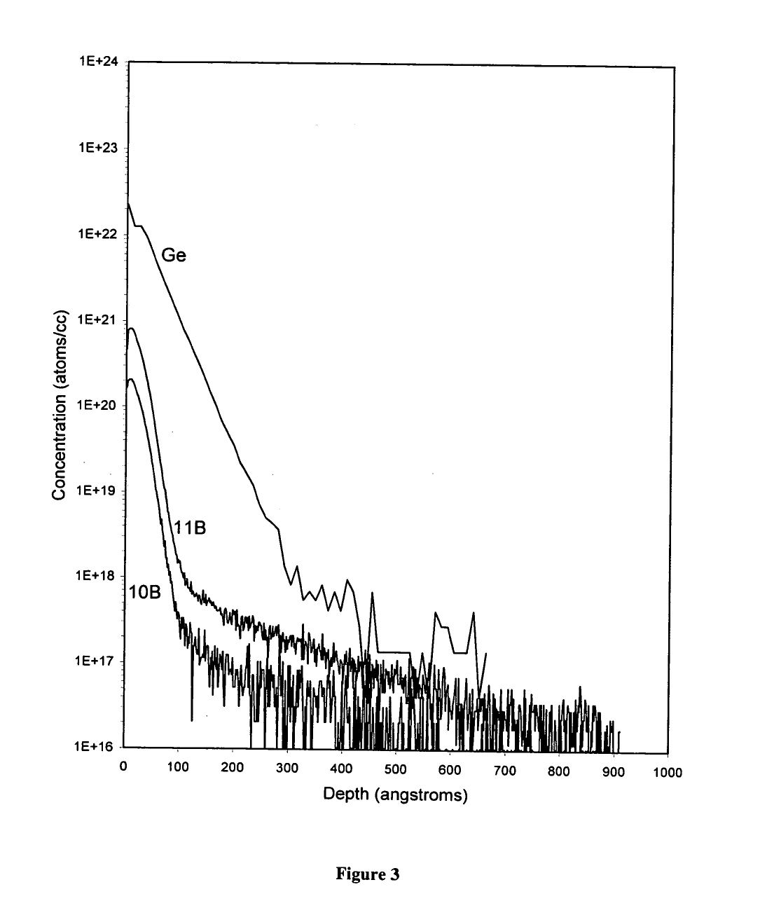

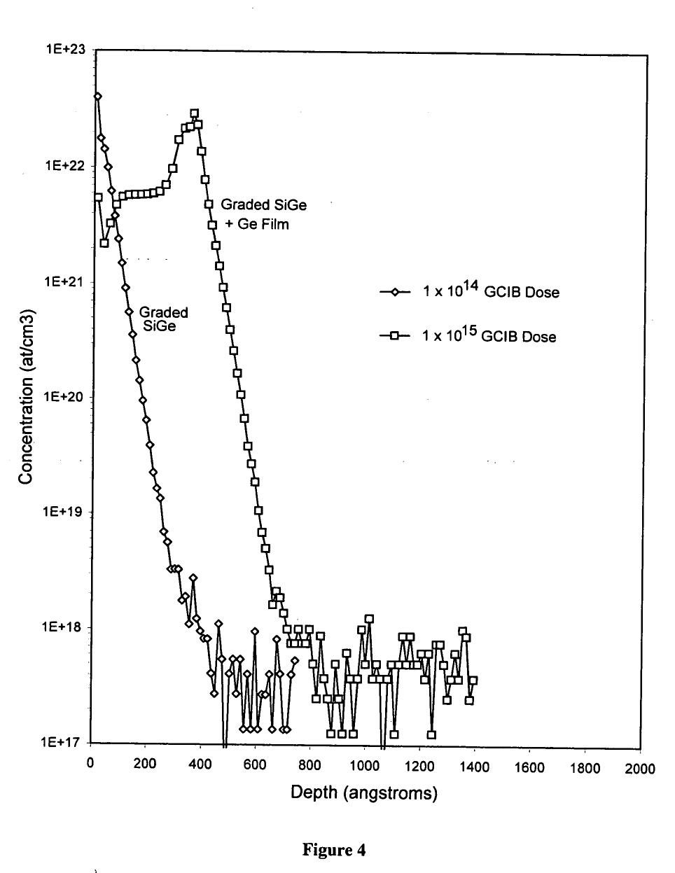

FIG. 4 is a graph showing results of SIMS measurements of two films formed by GCIB infusion as may be employed for practice of the invention. In these examples, two similarly processed silicon semiconductor wafer samples are compared. A gas-cluster ion beam processing system similar to that shown in FIG. 2 was used to process the surface of both silicon semiconductor wafers. For both samples, a mixture of 5% germane (GeH₄) in argon was used as the source gas for gas-cluster formation. In both cases, the ionized gas-cluster ion beam was accelerated by 5 kV acceleration voltage and for the first sample a dose of 1×10¹⁴ gas-cluster ions/cm² was irradiated onto the silicon wafer, while for the second sample a dose of 1×10¹⁵ gas-cluster ions/cm² was irradiated onto the silicon wafer. For the first (lower dose) sample, SIMS analysis confirms that a film of approximately 200 angstroms depth is infused with germanium ions and has resulted in a graded SiGe layer, high in germanium concentration at the surface, grading to substantially pure silicon at a depth of about 200 angstroms and greater. For the higher dose sample, the SIMS analysis shows approximately 200 angstroms of silicon infused with germanium (forming graded SiGe), with approximately 500 angstroms of additional germanium film deposited or grown on top of the germanium-infused silicon layer. The SIMS concentration axis is not accurately calibrated, but surface XPS measurements confirm infusion of germanium into silicon in the lower dose sample and pure germanium surface film in the higher dose sample. In the low dose case a germanium-infused graded SiGe with a high surface concentration of Ge has been formed, while in the higher dose case, a germanium film has been deposited or grown on the silicon substrate, with a graded SiGe interface region. This confirms that by gas-cluster ion beam infusion of Ge, a germanium surface layer with a graded SiGe interface is created and that by selectively choosing the GCIB dose, the thickness of the surface Ge region can be chosen and controlled. Furthermore, when the germanium infusion is done with a dopant atom incorporated into the gas-cluster ions (as illustrated in FIG. 3), the SiGe and/or Ge region is simultaneously doped (p-type or n-type depending on choice of dopant gas incorporated) and may be subsequently annealed and activated by thermal processing.

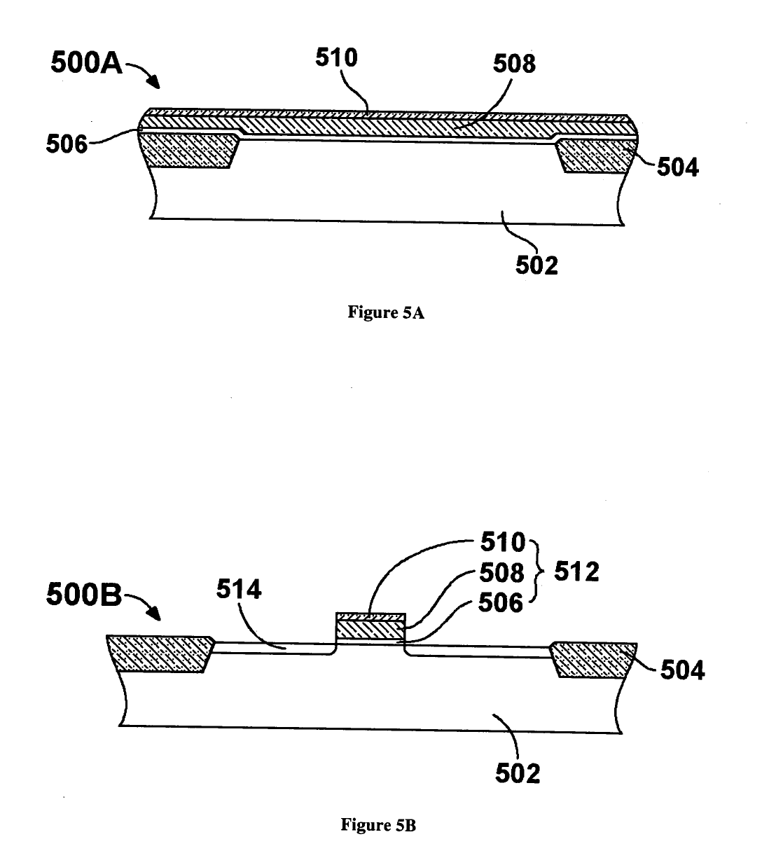

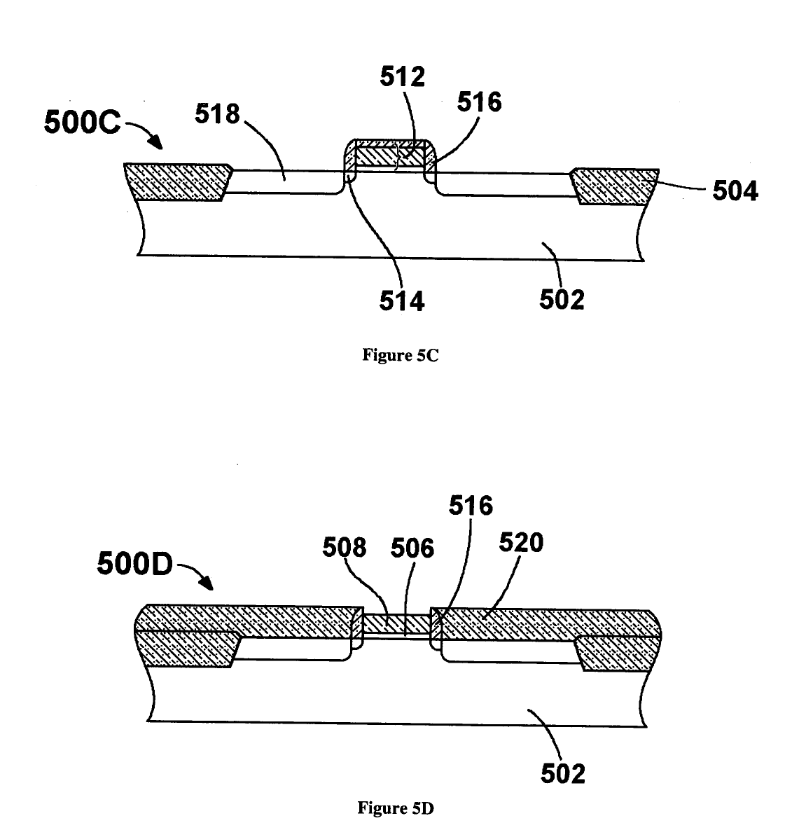

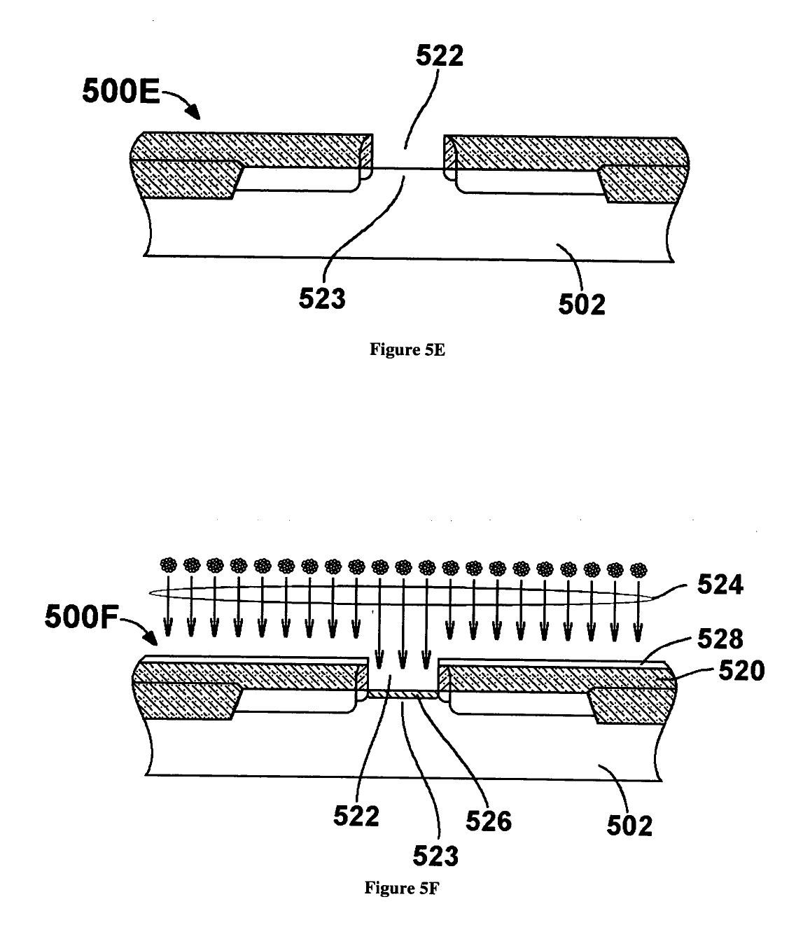

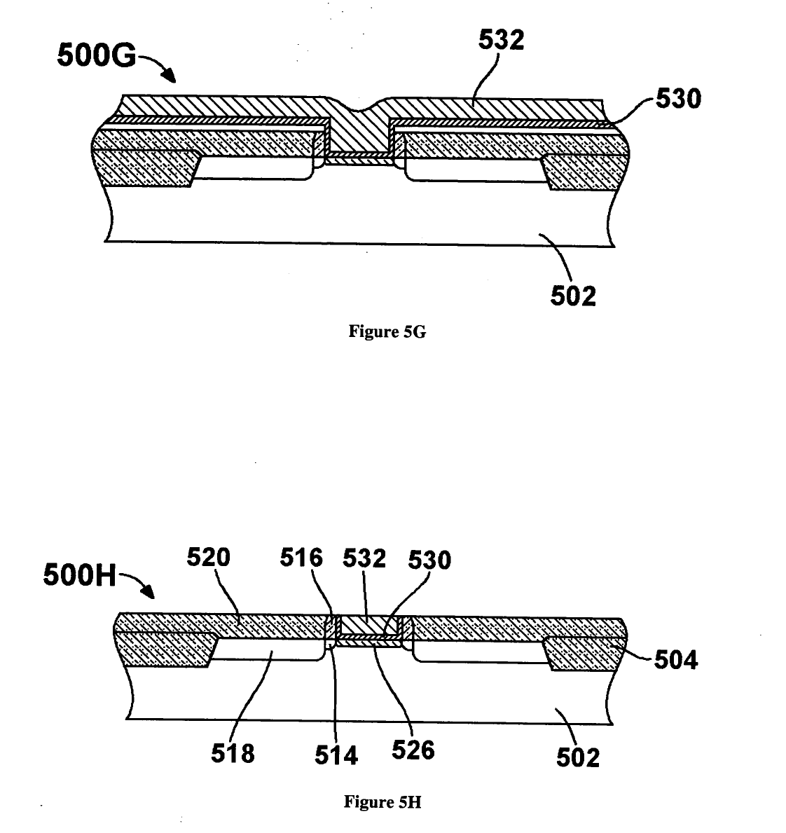

For clarity of explanation, FIGS. 5A through 5H are not necessarily shown to scale.

FIG. 5A shows a schematic of a step in fabricating an embodiment of the invention, namely the formation of an n-channel enhancement mode MISFET according to the invention. FIG. 5A represents an early stage 500A in the formation of an n-channel MISFET using a “replacement gate” process flow. A semiconductor substrate 502 is preferably a p-type (doped and activated) monocrystalline silicon substrate or a p-type (doped and activated) monocrystalline silicon-on-insulator substrate (insulator layer of silicon-on-insulator substrate is not illustrated). Alternatively, and not shown, rather than p-type substrate, the substrate could be a p-type well in an n-type substrate. Insulating regions 504 (for example, isolation trenches filled with SiO₂) have been formed to provide isolation from adjacent regions of the semiconductor substrate 502. An oxide film 506 (for example, hot-formed SiO₂ having a thickness of a few tens of angstroms) overlies the semiconductor substrate 502 and the insulating regions 504. A silicon film 508 (for example, polycrystalline silicon having a thickness of about 1000 angstroms) overlies the oxide film 506. A silicon nitride film 510 (for example, a few hundred angstroms thick) overlies the silicon film 508.

FIG. 5B shows a later processing stage 500B than FIG. 5A. Using conventional mask formation techniques and conventional etching techniques a dummy gate structure 512, comprising unetched remnants of the oxide film 506, the silicon film 508, and the silicon nitride film 510, has been formed. A self aligned source/drain extension region 514 has been formed by ion implantation using the dummy gate structure 512 as a mask. At this stage, additional optional conventional ion implantation steps as for example anti-punch-through/HALO/pocket implants may be added as desired according to known techniques.

FIG. 5C shows a later processing stage 500C than FIG. 5B. A sidewall spacer 516 has been formed by conventional techniques on the sidewalls of dummy gate structure 512. At this stage, additional optional conventional ion implantation steps as for example anti-punch-through/HALO/pocket implants may be added as desired according to known techniques. Using conventional ion implantation, source/drain regions 518 are formed using the dummy gate structure 512 with sidewall spacer 516 as a mask. The implanted source/drain regions 518 and extension regions 514 as well as any of the optional conventional implants are activated and annealed by a thermal treatment, which may be performed at this stage or alternatively at a later stage of processing.

FIG. 5D shows a later processing stage 500D than FIG. 5C. A thick interlayer dielectric film 520 (for example silicon dioxide) has been deposited and planarized by conventional techniques and the silicon nitride film 510 remnant has been removed by conventional etching technique.

FIG. 5E shows a later processing stage 500E than FIG. 5D. The silicon film 508 remnant and the oxide film 506 remnant are both removed by conventional etching techniques, thus completely removing the dummy gate structure 512 and leaving a gate opening 522 to the exposed surface of the channel region 523 of the MISFET being fabricated. In a conventional “replacement gate” process flow, the next step would typically be formation of the high-k dielectric gate insulator in the gate opening 522, however according to the invention the next step is shown in FIG. 5F.

FIG. 5F shows a later processing stage 500F than FIG. 5E. A gas-cluster ion beam 524 uniformly irradiates and infuses the surface of the interlayer dielectric film 520 and, through the gate opening 522 infuses the channel region 523. By using a gas-cluster ion beam 524 preferably formed of gas-cluster ions comprising (for example) a mixture of argon, a germanium-containing gas, and a dopant gas (boron-containing gas for p-type doping, e.g. diborane (B₂H₆) or other boron containing gas) a p-doped germanium infused layer 526 is formed in the surface of the channel region 523. By using preferred gas-cluster ions comprising both germanium and a dopant, a doped film is formed by GCIB infusion, however it is alternatively possible to omit the dopant component, infusing germanium and then subsequently doping by a more conventional method. It is also possible to perform two separate GCIB infusion steps, one a GCIB infusion of germanium and one a GCIB infusion of dopant. Of course, by any of the GCIB infusion methods, the germanium/dopant infused layer 528 is also formed in the surface of the interlayer dielectric film 520, which serves as a mask for the channel region infusion process. Selection of gas-cluster ion beam dose and energy parameters controllably determines whether the infused layer 526 is a graded SiGe film, or a Ge film on a graded SiGe film and controls the thickness of the layer as shown earlier in FIG. 4. The relative concentrations of germanium and dopant in the gas-cluster ion beam are selectable to control the doping level in the infused germanium layer. The p-doped germanium infused layer 526 is activated and annealed with a thermal treatment exceeding about 550 degrees C. By suitable choice of parameters, this same thermal treatment can also serve to activate the dopant implanted in the previously formed source/drain regions, source drain extension regions and any other optional implants performed in the source/drain or extension regions. The infusion process can result in production of a germanium infused layer 526 that has a thin undesirable GeO surface layer (not shown) resulting from residual gas in the vacuum system during infusion. The annealing and activating thermal treatment also serves to remove the GeO surface layer. Optionally, a separate operation using conventional cleaning techniques can be used to remove the GeO surface layer prior to proceeding to the next step. The infused layer 526 formed by GCIB irradiation of the channel region 523 of the silicon substrate 502 is described herein as lying or being formed “in” or “on” or “at” the surface of the channel region or the surface of the silicon substrate. The terms “in”, “at”, and “on”, used in this context, is intended to convey the concept that the infused layer forms in such a way that a portion of it is “in” or beneath the original surface of the substrate, but that depending on the infusion parameters, a portion of the infused layer may form or grow “on” or on top of the original substrate. It is also readily understood that a Ge infused layer may be formed using the methods described herein but without the inclusion of a dopant material.

FIG. 5G shows a later processing stage 500G than FIG. 5F. A high-k dielectric gate insulator film 530 (for example a hafnium-based dielectric or other high-k dielectric including silicon oxynitride) is deposited by conventional techniques. A gate material 532, which is preferably metal, but which may alternatively be polysilicon, is deposited using conventional gate formation techniques.

FIG. 5H shows a later processing stage 500H than FIG. 5G. The entire surface is planarized (by for example, chemical mechanical polishing) to remove excess gate material 532 and to remove excess high-k dielectric 530 and to remove the germanium infused layer 528 from the interlayer dielectric film 520. The residual gate material 532 forms the gate for the fabricated n-channel enhancement mode MISFET. According to conventional technology, interconnection lines may be added to complete more complex circuits.

Although the transistor of the invention has been described as an n-channel enhancement mode MISFET, it will be understood by those skilled in the art, that the invention can be practiced for p-channel enhancement mode MISFETs and n-channel and p-channel depletion mode MISFETs by appropriate selection of the p- or n-type of the substrate (or well) and by selection of the doping levels in the various doping steps (all according to known techniques). In each case, however, gas-cluster ion beam infusion of germanium and dopant (of proper type and dose) through an opening to the channel region during a “replacement gate” process flow and with subsequent low-temperature anneal and activation is essential. Further, although the invention has been described in terms of films or layers comprising various compounds (such as, for example, SiO₂, Si₃N₄, SiON, HfSiON, HfSiO, HfAlO, SiGe, GeO, Ge, silicon dioxide, silicon oxynitride, silicon nitride, hafnium silicate, nitrided hafnium silicate, hafnium aluminate, silicon germanium, germanium oxide, and germanium) it will be understood by those skilled in the art, that many of the films and layers formed in practicing the invention are graded and that even in the purest forms, they do not have the precision stoichiometries implied by the chemical formulas or names, but rather have approximately those stoichiometries and may additionally include hydrogen and/or other impurities as is normal for such films used in analogous applications. As used herein, the term “silicon substrate” is intended to include silicon substrates, silicon-on-insulator substrates, and other substrates comprising an uppermost layer that is substantially silicon (for FET fabrication) with other underlying material(s) compatible with fabricating semiconductor devices in the silicon.

Although the invention has been described with respect to various embodiments, it should be realized this invention is also capable of a wide variety of further and other embodiments within the spirit of the invention and the claims.

What is claimed is:

1. A method of forming a semiconductor MISFET device, comprising the steps of:
forming a dummy gate structure on a selected region of a semiconductor substrate;
forming a sidewall spacer on at least one sidewall of the dummy gate structure;
forming at least one source/drain region using the dummy gate structure and the at least one sidewall spacer as a mask;
forming an interlayer dielectric film adjacent to the dummy gate structure;
removing the dummy gate structure and exposing an underlying semiconductor channel region;
irradiating the exposed channel region by GCIB to form an increased-mobility channel;
forming a high-k gate dielectric layer overlying the increased mobility channel; and
forming a gate electrode overlying the high-k gate dielectric.

2. The method of claim 1, wherein the GCIB comprises energetic gas-cluster ions comprising germanium, and further wherein the semiconductor substrate includes silicon.

3. The method of claim 2, wherein the gas-cluster ions further comprise a dopant species.

4. The method of claim 3, wherein the dopant species is selected from the group including the elements boron, phosphorous, , antimony, and arsenic (B, P, Sb, As).

5. The method of claim 1, wherein the GCIB comprises energetic gas-cluster ions comprising germanium, and further wherein the semiconductor substrate includes silicon-on-insulator.

6. The method of claim 1, wherein the increased-mobility channel includes graded SiGe.

7. The method of claim 1, wherein the increased-mobility channel includes Ge overlying graded SiGe.

8. A method of forming a semiconductor MISFET device, comprising the steps of:
forming a dummy gate structure on a selected region of a semiconductor substrate;
forming a wall structure around at least a portion of the dummy gate structure;
forming at least one source/drain region using the dummy gate structure and the wall structure as a mask;
removing the dummy gate structure and exposing an underlying semiconductor channel region;
irradiating the exposed channel region by GCIB to form an increased-mobility channel;
forming a high-k gate dielectric layer overlying the increased mobility channel; and
forming a gate electrode overlying the high-k gate dielectric.

9. The method of claim 8, wherein the step of forming a wall structure includes forming a sidewall spacer on at least one sidewall of the dummy gate structure.

10. The method of claim 8, further comprising the step of forming an interlayer dielectric film adjacent to the dummy gate structure or the wall structure.

11. A semiconductor MISFET device formed on a silicon substrate, comprising:
a channel as formed in the silicon substrate by irradiation with a gas-cluster ion beam using gas-cluster ions comprising germanium, to create infused germanium in the silicon substrate;
a high-k dielectric gate insulator overlying the channel; and
a gate electrode overlying the channel and the gate insulator.

12. The semiconductor MISFET device of claim 11, wherein the channel includes graded SiGe formed by gas-cluster ion beam irradiation using gas-cluster ions comprising germanium.

13. The semiconductor MISFET device of claim 12, wherein the graded SiGe is formed by gas-cluster ion beam irradiation using gas-cluster ions comprising germanium and a dopant species.

14. The semiconductor MISFET device of claim 12, wherein the channel includes germanium overlying the graded SiGe.

15. The semiconductor MISFET device of claim 13, wherein the overlying germanium is formed by gas-cluster ion beam irradiation using gas-cluster ions comprising germanium.

16. The semiconductor MISFET device of claim 14, wherein the overlying germanium is formed by gas-cluster ion beam irradiation using gas-cluster ions comprising germanium and a dopant species.

17. A semiconductor MISFET device formed on a silicon substrate, comprising:
a channel formed in the silicon substrate and including infused germanium for improved electron mobility;
a high-k dielectric gate insulator overlying the channel; and
a gate electrode overlying the channel and the gate insulator.

18. The semiconductor MISFET device of claim 17, wherein the channel includes graded SiGe.

19. The semiconductor MISFET device of claim 17, wherein the channel includes germanium overlying graded SiGe.

20. The semiconductor MISFET device of claim 17, wherein the channel includes graded SiGe or germanium overlying graded SiGe formed by gas-cluster ion beam irradiation with gas-cluster ions comprising germanium or germanium and a dopant species.
